(19) United States
(12) Patent Application Publication
(10) Pub. No.: US 2026/0371939 A1
(43) Pub. Date: Nov. 19, 2026

(54) QUANTUM COMPUTER AND SINGLE-ELECTRON/SINGLE-HOLE TRANSPORTING METHOD

(71) Applicant: Hitachi, Ltd., Tokyo (JP)

(72) Inventors: Takeru UTSUGI, Tokyo (JP); Takuma KUNO, Tokyo (JP); Noriyuki LEE, Tokyo (JP); Toshiyuki MINE, Tokyo (JP); Ryuta TSUCHIYA, Tokyo (JP); Digh HISAMOTO, Tokyo (JP); Tomonori SEKIGUCHI, Tokyo (JP)

(21) Appl. No.: 19/146,589

(22) PCT Filed: Mar. 2, 2023
(86) PCT No.: PCT/JP2023/007794

§ 371 Date: Jul. 9, 2025

(51) Int. Cl. H10N 60/10; B82Y 10/00; G06N 10/40

(52) U.S. Cl. CPC H10N 60/128; G06N 10/40; H10N 60/11; B82Y 10/00

(57) ABSTRACT

In a preferred aspect of the present invention, a quantum computer includes: a gate electrode array disposed on a semiconductor crystal base; a single-electron manufacturing unit for extracting a single electron; and an electron transport path including a branch and serving as a transport path of the single electron in the semiconductor crystal base, and a path as a branch destination of the single electron is selected by controlling the gate electrode array.

### TECHNICAL FIELD

This invention relates to a quantum computer and a single-electron/single-hole transporting method.

### BACKGROUND ART

It is considered that a quantum computer can perform higher-speed information process as compared with an existing computer. The existing computer uses binary numbers of 0 and 1 while a quantum computer is characterized by that it can use a superposition state of those values.

To use a superposition state, a quantum computer needs an element realizing a qubit (quantum bit). A qubit can be realized by using a quantum dot or the like by a superconducting element, a cold atom, a photon, or a semiconductor element. Basic operations of a quantum computer include initialization, computation, and reading. It is known that, as further basic computation, there are a single-qubit gate, a two-qubit gate, and the like, and universal quantum calculation can be realized by combination of them. For example, in each operation of a quantum computer using an electron for a qubit, an electron has to be transported.

Patent Literature 1 discloses a well-known electron transporting method by a charged coupled device. Patent Literature 2 discloses a method of transporting a single electron.

That is, a method of transporting electrons one by one to a quantum dot has been examined. Specifically, Patent Literature 1 discloses a well-known electron transporting method by a charge coupled device (CCD). Patent Literature 2 discloses an electron transporting method using the Coulomb blockade phenomenon. It is, however, considered that Patent Literature 1 does not disclose a method of moving a single electron to a desired position, and Patent Literature 2 does not disclose transportation of an electron on a quantum dot array having a two-dimensional array structure (two-dimensional quantum dot array) of high expandability.

### CITATION LIST

### Patent Literature

Patent Literature 1: Specification of U.S. Patent Publication No. 2020027972
Patent Literature 2: Japanese Unexamined Patent Application Publication No. 2004-63495

### SUMMARY OF INVENTION

### Technical Problem

When transportation on a quantum dot array is examined, in order to transport an electron or the like to a desired quantum dot on a two-dimensional quantum dot array, a desired path through a plurality of branch paths has to be selected. Consequently, an object of the present invention is to provide a technique of performing excellent path selection (routing) in branch paths in a transport path.

### Solution to Problem

According to a first aspect of the present invention, a quantum computer described below is provided. The quantum computer includes: a gate electrode array disposed on a semiconductor crystal base; a single-electron manufacturing unit for extracting a single electron; and an electron transport path including a branch and serving as a transport path of the single electron in the semiconductor crystal base. The quantum computer selects a path as a branch destination of the single electron by controlling the gate electrode array.

According to a second aspect of the present invention, a quantum computer described below is provided. The quantum computer includes: a gate electrode array disposed on a semiconductor crystal base; a single-hole manufacturing unit for extracting a single hole; and a hole transport path including a branch and serving as a transport path of the single hole in the semiconductor crystal base. The quantum computer selects a path as a branch destination of the single hole by controlling the gate electrode array.

According to a third aspect of the present invention, a single-electron/single-hole transporting method described below is provided. The single-electron/single-hole transporting method of transporting a single electron or a single hole, includes: a step of transporting a single electron/single hole along a transport path in a semiconductor crystal base by using a gate electrode array; and a step of selecting a path as a branch destination of the single electrode/single hole by controlling a voltage of a gate electrode disposed in a position immediately after the branch in the transport path.

Advantageous Effects of Invention According to the present invention, a quantum computer and a single-electron/single-hole transporting method capable of performing excellent path selection in a branch path in a transport path at the time of transporting an electron or the like is provided. Objects, configurations, and effects other than the above will be apparent from the description of the following embodiments.

### BRIEF DESCRIPTION OF DRAWINGS

FIG. 1 is a diagram illustrating an example of a Structure of a qubit array.

FIG. 2A is a schematic diagram of an example of the structure of the qubit array illustrated in FIG. 1.

FIG. 2B is a diagram illustrating an example of transporting an electron in the left direction.

FIG. 2C is a diagram illustrating an example of transporting an electron in the right direction.

FIG. 3A is a top view of a two-dimensional quantum dot array and is an outline diagram illustrating an example of transport of an electron.

FIG. 3B is a diagram illustrating an example of a path branch part.

FIG. 4A is a diagram illustrating an example of path selection in electron transport.

FIG. 4B is a diagram illustrating an example of path selection in electron transport in a structure different from that of FIG. 4A.

FIG. 4C is a schematic diagram illustrating an example of voltage applied to each gate electrode.

FIG. 4D is a schematic diagram illustrating an example of voltages applied to gate electrodes in the case of performing complicated path selection.

FIG. 5A is an outline diagram illustrating an example of a device structure for experiment having a quantum dot array and two branch paths.

FIG. 5B is an outline diagram illustrating an example of potentials and input voltage waveforms.

FIG. 5C is a diagram illustrating an example of an experiment result of a single-electron pump used to prepare a single electron.

FIG. 6 is a diagram illustrating an example of a result of measuring DC characteristics of gate electrodes for path selection.

FIG. 7A is a diagram illustrating an example of a result of measuring currents of right and left drains in the case where AC voltage is not applied to an assist gate electrode.

FIG. 7B is a diagram illustrating an example of a result of measuring currents of right and left drains in the case where AC voltage is applied to the assist gate electrode.

FIG. 7C is a diagram illustrating an example of a result of demonstrating a programmable router operation.

FIG. 7D is a diagram illustrating an example of a result of demonstrating a programmable router operation.

FIG. 8 is a diagram illustrating an example of an electron transport and path selecting method in the case of a structure in which gate electrodes in the vertical direction are continuous in a two-dimensional qubit array.

FIG. 9A is a diagram illustrating an example of a system block diagram of a quantum computer.

FIG. 9B is a diagram illustrating an example of a method of generating a control sequence in a voltage control unit.

FIG. 10 is a diagram illustrating an example of a calibrating method in a part of a path on a quantum dot array.

FIG. 11 is a diagram illustrating an example of a whole configuration of a quantum computer system.

### DESCRIPTION OF EMBODIMENTS

One embodiment of the invention will now be described with reference to the drawings. The present invention, however, is not interpreted by being limited to the following description of the embodiments. A person skilled in the art will easily understand that a concrete configuration can be changed without departing from the idea or gist of the present invention.

In the configuration of the following embodiments, the same reference numeral will be used to the same part or a part having a similar function commonly in different drawings, and repetitive description may be omitted. In the case where there are a plurality of elements having the same or similar function, description may be given by attaching different suffixes to the same sign. It is to be noted that the description may be given without suffixes.

Writing such as “the first”, “the second”, and “the third” in the specification is to identify components and does not always limit the number, order, or content. A number for identifying a component is used by context, and a number used in a context does not always refer to the same configuration in another context. A component identified by a certain number is not hindered from also having the function of a component identified by another number.

The position, size, shape, range, and the like of each of the configurations illustrated in the diagrams and the like may not express the actual position, size, shape, range, and the like in order to make the present invention easily understood. Therefore, the present invention is not limited to the positions, sizes, shapes, ranges, and the like disclosed in the diagrams and the like.

In the embodiment, an example of a device of integrating qubits and a method of controlling a device will be described. In the embodiment, for example, a technique of transporting a single electron (or single hole) among quantum dots in a quantum dot array in order to realize a quantum computer by a quantum dot array structure will be described in detail.

Necessity of electron transport in a quantum computer using a semiconductor element will be described. Electron transport is an operation of moving a single electron from a certain position to a desired quantum dot.

In initialization of a quantum computer, as an example, first, by applying a voltage to a gate electrode formed in a semiconductor device, a fine potential structure capable of confining electrons one by one is formed in the semiconductor. From a reservoir in which a number of free electrons exist, an electron is confined in the potential by electron transport. Further, by adjusting spins of electrons (the degree of freedom used as a qubit), the qubit is initialized. The electron transport for initialization will be called “load” or “loading”.

Secondly, in computation, there is a case of transporting an electron to a quantum dot region in which quantum gate operation can be performed. Further, in a two-qubit gate, desired two qubits are transported to neighboring quantum dots, and a gate operation is realized by using an effect of interaction between the two qubits. In the case of transporting an electron at the time of computation in such a manner, the electron has to be transported while maintaining a quantum state including phase information of electron spins. The electron transport for such computation will be called “shuttle” or “shuttling”.

Finally, in reading, an electron has to be transported to a quantum dot region in which reading is possible. In the case of reading the state of a qubit, it is sufficient that information called spin polarization (up and down of a spin) or amplitude is retained. It is unnecessary to retain phase information. The electron transport for the reading will be called “carry-out”.

As described above, to realize a quantum computer, it is important to establish transport techniques such as “loading”, “shuttling”, and “carry-out”.

Single-electron transport on a two-dimensional quantum dot array will now be examined. It is necessary to consider the following challenges.

To transport an electron to a desired quantum dot on a two-dimensional quantum dot array, it is necessary to transport an electron from a position where the electron exists at present through a plurality of branch paths. Each of the branch paths is, for example, a two-branch path or a three-way branch path, and a desired path has to be selected.

In a normal electric circuit, bias voltage which is positive is applied to a direction in which an electron is desired to flow. In a large-scale quantum dot array, however, it is considered to be uneasy to control the bias voltage. The reason is that when a bias voltage is applied, unintended electron inflow or outflow occurs. It is consequently desired to control an electron transport path by performing desired path selection (routing) under the condition that the bias voltage is 0V.

Although the electron transport has been described specifically, also in the case of performing hole transport of transporting a single hole in a two-dimensional quantum dot array, there is similarly a challenge that a desired path can be selected. Therefore, an object of the present invention is to provide a technique of performing stable path selection (routing) in a branch path in an electron transport path (or hole transport path). Hereinafter, an embodiment of achieving the object will be described.

### Embodiments

### Qubit Array

A quantum computer of a type of setting an electron spin using a semiconductor element as a qubit will be described in detail. The quantum computer has a two-dimensional qubit array. The qubit is a spin qubit setting the spin of a carrier (electron or hole, an electron will be assumed in the following description but it may be a hole) in a semiconductor to the degree of freedom. There is Japanese Unexamined Patent Application Publication No. 2021-27142 proposing a two-dimensional qubit array.

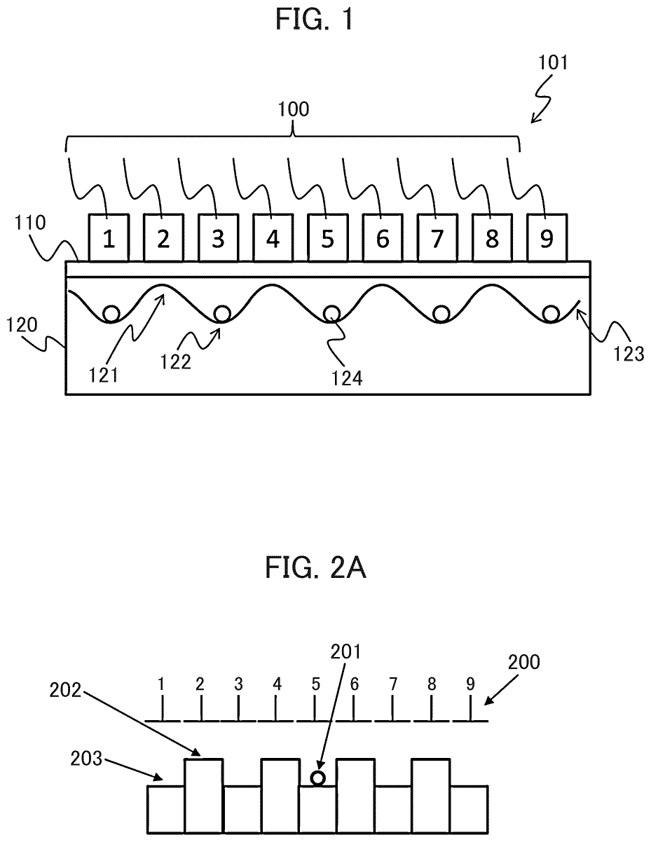

FIG. 1 illustrates the structure of a quantum dot 122 for forming a qubit array 101. The qubit array 101 indicates a state where a plurality of electrons 124 are held by a plurality of quantum dots 122. The quantum dot 122 has an electromagnetic field structure capable of holding one or more electrons by controlling a potential 123 by an electromagnetic field, and each quantum dot 122 is separated by a potential barrier 121. The qubit array 101 is mounted in a chip which is placed at extremely low temperature such as a few mK (millikelvin) to a few K (kelvin), and is operated in a region in which thermal fluctuations can be ignored. In the following description, a situation where thermal fluctuations and excitation can be ignored will be assumed.

FIG. 1 schematically illustrates a structure (gate electrode array) in which gate electrodes 100 based on the MOS (Metal-Oxide-Semiconductor) of a semiconductor are arranged one-dimensionally, and the potentials 123 in a silicon channel 120 while sandwiching an oxide film 110 from each gate electrode. When the gate electrodes 100 disposed on a semiconductor substrate are numbered as 1 to 9 in order from the left, the quantum dots 122 exist just below the odd-numbered gate electrodes, and the potential barriers 121 exist just below the even-numbered gate electrodes. In the diagram, one electron 124 is held by one quantum dot 122. However, according to circumstances, the quantum dot 122 may hold no electron or two or more electrons. The quantum dot 122 is formed so as to be able to hold one or more electrons.

A quantum computer by a qubit array realizes quantum computation by controlling a spin state by interaction of an electron and a microwave or electrons using the spin of an electron held by each quantum dot as a qubit.

### One-Dimensional Electron Transport

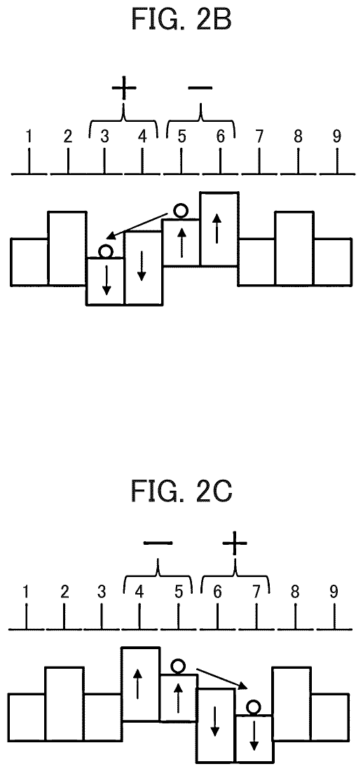

FIG. 2A schematically illustrates the qubit array in FIG. 1, which is simplified. An electron 201 is held by a quantum dot 203 just below the fifth gate electrode. The structure of a gate electrode 200 is controlled or voltage applied to the gate electrode 200 is adjusted so that the potential of the quantum dot 203 becomes lower than the potential of a potential barrier 202.

A method of transporting the electron 201 to another quantum dot for the above-described “loading”, “shuttling”, and “carry-out” will be described.

FIG. 2B illustrates an example of transporting the electron 201 in the left direction in the case of FIG. 2A. For transportation in the left direction, voltage is applied in the negative direction with respect to the present state to the fifth and sixth gate electrodes to increase the potential, and voltage is applied in the positive direction with respect to the present state to the third and fourth gate electrodes to decrease the potential. By the operation, the electron moves in the left direction. When the voltage is put back to the original state, the electron can be moved to the quantum dot just below the third gate electrode.

On the contrary, FIG. 2C illustrates an example of transporting the electron 201 in the right direction. For transportation in the right direction, voltage is applied in the negative direction with respect to the present state to the fourth and fifth gate electrodes to increase the potential, and voltage is applied in the positive direction with respect to the present state to the sixth and seventh gate electrodes to decrease the potential. By the operation, the electron moves in the right direction. When the voltage is put back to the original state, the electron can be moved to the quantum dot just below the seventh gate electrode.

When the position where the electron exists at present is just below the Nth gate electrode, by applying voltage in the negative direction to the Nth and (N+1)th gate electrodes and applying voltage in the positive direction to the (N−1)th and (N−2)th gate electrodes, the electron can be moved to the quantum dot just below the (N−2)th gate electrode. By applying voltage in the negative direction to the Nth and (N−1)th gate electrodes and applying voltage in the positive direction to the (N+1)th and (N+2)th gate electrodes, the electron can be moved to the quantum dot just below the (N+2)th gate electrode.

### Two-Dimensional Electron Transport

By combining the above-described operations, a single electron can be transported to a desired position on a one-dimensional array. On the other hand, by expanding the above to a two-dimensional array, larger scale of the quantum computer is realized.

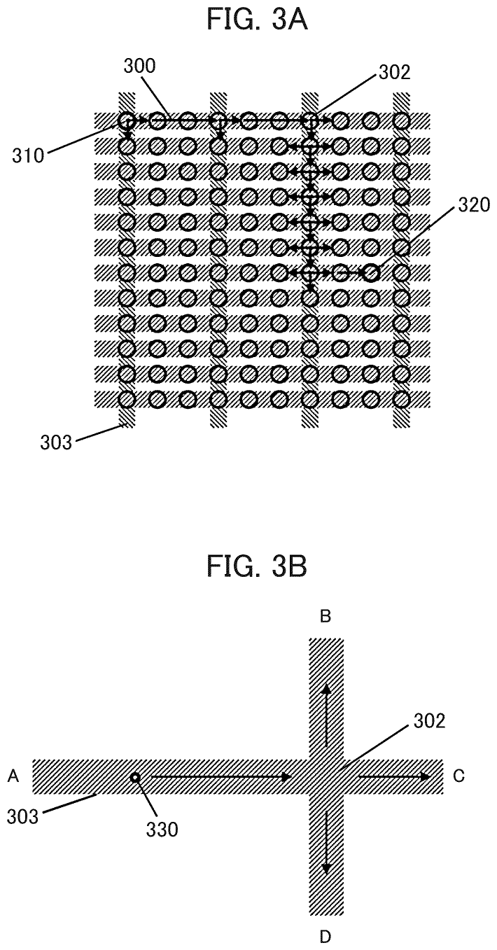

FIG. 3A is a top view of a two-dimensional quantum dot array and is an outline diagram expressing electron transport. Channels 303 (electron transport paths) as electron paths are arranged in a two-dimensional lattice shape, and quantum dots exist on the channels. The structure of a gate electrode and the like is omitted here. The sectional structure of the channel is similar to that in FIGS. 1 and 2. A gate electrode array is disposed above the two-dimensional lattice-shaped channels 303. The case where an electron exists in a quantum dot 310 and is transported to a quantum dot 320 will be considered. For example, it can be realized by transporting an electron along an electron path 300. In quantum dots on the path, the electron passes through a plurality of branch paths 302 as depicted by the arrows in the diagram. At the branch path, path selection to selectively move the electron to a desired path is necessary. For example, at a branch as illustrated in FIG. 3B, an electron 330 enters from A and has to be transported by selecting one of three paths B, C, and D at the branch path 302. How the path selection at such a branch path is realized in transport of a single electron will be described hereinafter.

### Path Selecting Method

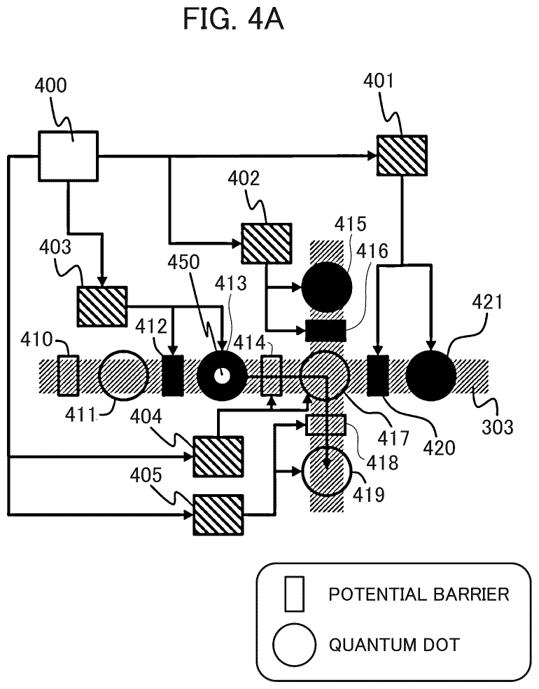

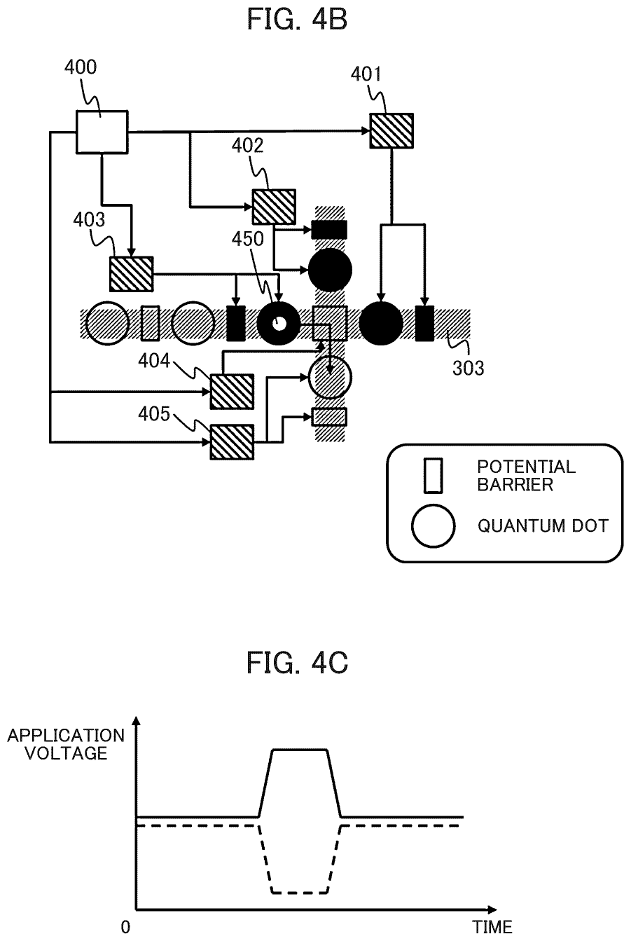

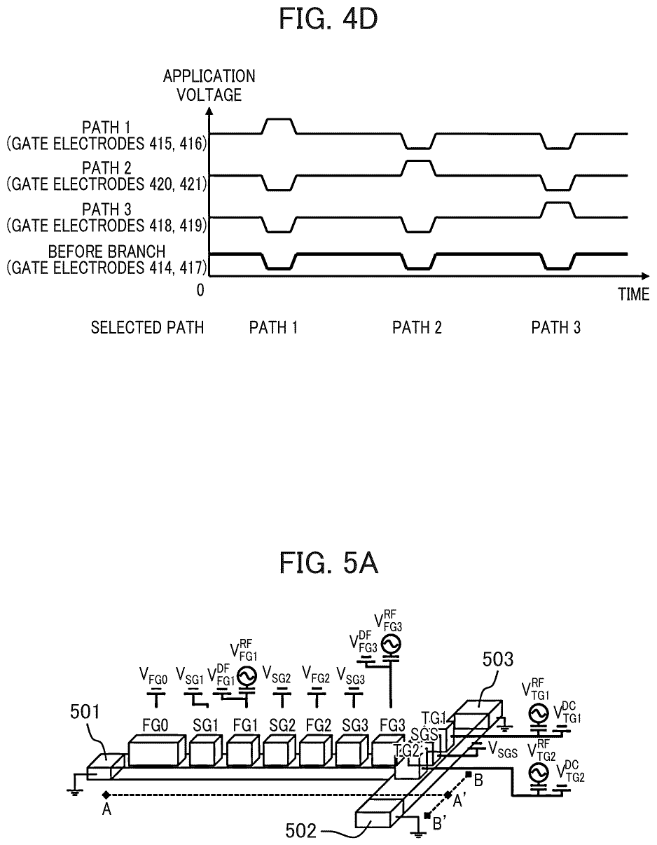

A path selecting method in electron transport will be described with reference to FIGS. 4A and 4B. FIG. 4A illustrates an example of a path selecting method in electron transport. An electron 450 exists in a quantum dot 413 in the example of FIG. 4A. FIG. 4A illustrates an example of a method of transporting the electron 450 to a quantum dot 419. First, voltage control units (401, 402, 403, 404, and 405) are connected to a synchronization signal generation unit 400 (timing control unit) and are synchronized by the same clock. Further, each of the voltage control units (401, 402, 403, 404, and 405) can apply voltage to a gate electrode just above a quantum dot and a potential barrier which are connected by the arrows.

Since the electron 450 exists in the quantum dot 413, voltage is applied in the negative direction to the quantum dot 413 and a potential barrier 412 from the voltage control unit 403. Simultaneously, voltage in the negative direction is applied also to quantum dots (415 and 421) and potential barriers (416 and 420) by the voltage control units (401 and 402). Further, at the same time, the voltage in the positive direction is applied to quantum dots (417 and 419) and potential barriers (414 and 418) by the voltage control units (404 and 405). In the diagram, solid black (white) indicates application of voltage in the negative (positive) direction.

By the above, the electron 450 is transported from the quantum dot 413 to the quantum dot 419 via the quantum dot 417. It is important that all of voltage changes are roughly synchronized by clocks. When the timings are asynchronous, it becomes uneasy to transport an electron to a desired quantum dot.

The voltage is applied from the voltage control unit to each of the quantum dot and the potential barrier. The value of the application voltage is adjusted in advance in each of the gate electrodes. In this method, by synchronously applying the voltage in the negative direction to the quantum dot in which an electrode to be transported exists and the potential barrier on the side opposite to the transport direction and the quantum dots and the potential barriers in the direction to which the electron is not transported in the branch paths, and the voltage in the positive direction to the quantum dot and the potential barrier on the transport path, the electron can be transported to the desired quantum dot in the branch path.

In the above-described method, it is assumed that a voltage is changed almost instantaneously (that is, like a rectangular waveform). The invention, however, is not limited to the above. For example, the voltage may be changed in a cyclic manner like a sine wave or the like. In this case, the influence that the waveform of a signal becomes rounded by the influence of a wire from the voltage control unit to the gate electrode or the like is reduced. There is consequently the possibility that the controllability improves. Even in a voltage change like a rectangular wave, a sine wave, or an intermediate wave of those waves, the timings of voltage changes in the positive or negative direction of the voltage control units have to be roughly synchronous. In other words, in the case of cyclic changes, the phase of the voltage change in the positive direction and that in the negative direction have to be deviated by almost 180°.

An example of controlling the timings and phases of voltages in the gate electrodes will be described. FIG. 4C is a schematic diagram of voltages applied to the gate electrode. The solid line indicates the voltage applied to blank electrodes (that is, electrodes related to blank parts) in FIGS. 4A and 4B, and the dotted line indicates the voltage applied to solid electrodes (that is, electrodes related to solid parts) in FIGS. 4A and 4B. When the voltage is increased, the potential to the electron decreases. By applying two kinds of the gate electrode application voltages at the same timing as illustrated in FIG. 4C, the path selection can be performed correctly.

FIG. 4D illustrates an example of performing more complicated path selection, and illustrates an example of cyclic operation. The sequences of voltages applied to the gate electrodes in a path 1 (path on the upper side of the branch in the diagram), a path 2 (path on the right side of the branch in the diagram), and a path 3 (path on the lower side of the branch in the diagram) as paths as branch paths in FIG. 4A are illustrated. In the example, the electron can be sequentially transported first to the path 1, then to the path 2, and finally, to the path 3. Also for the complicated path selection control as described above, by synchronizing the timings, decreasing the voltage to the gate electrode before the branch and the gate electrode application voltage in the path other than the transport destination path and increasing the gate electrode application voltage of the transport destination path, desired path selection can be performed.

In the above-described method, there is a case where an electron remains in the quantum dot 417. Consequently, for example, after the above-described procedure, by two steps of applying the voltage in the negative direction to the potential barrier 414 and the quantum dot 417 by the voltage control unit 404, an electron can be transported stably to a quantum dot (for example, the quantum dot 419 in FIG. 4A).

In the above-described method, one potential barrier and one gate electrode for a quantum dot are connected to one voltage control unit. Since this combination of the connections varies depending on the electron transport direction and the transport path, by making it changeable, the degree of freedom of the electron transporting method becomes higher.

In the above-described method, the potentials of both of the quantum dot and the potential barrier are controlled. For example, it is also possible to simplify the control circuit by controlling only the potential barrier, and use a potential change in a neighboring quantum dot by capacitance coupling.

Although there are a plurality of voltage control units in the above-described method, for example, by a method such that a voltage generation unit and a voltage modulation unit are separated, the efficiency of the configuration of the voltage control unit can be increased.

The structure of FIG. 4B is similar to that of FIG. 4A but is different with respect to the point that there is the potential barrier in the center of the branch paths. In this case as well, the electron 450 can be transported to a desired quantum dot by a similar method (that is, a method of, in synchronization with a timing, decreasing the gate electrode application voltage in the paths other than the transport destination path and increasing the gate electrode application voltage in the transport destination path). Since a quantum dot before transport and a quantum dot after the transport are neighboring quantum dots separated only by one potential barrier in the branch path center, a path can be selected by one step without remaining of the electron.

### Demonstration Experiment

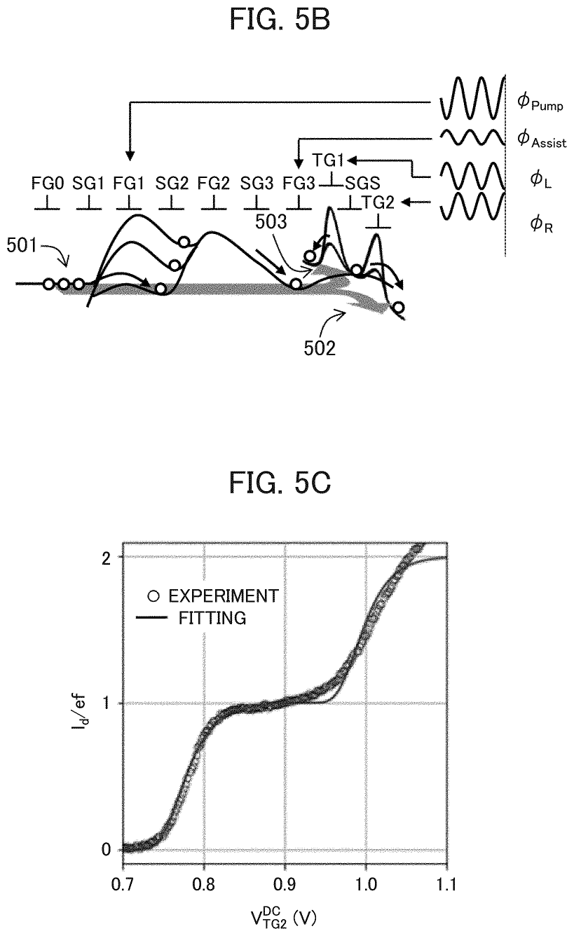

A demonstration experiment on single-electron path selection will be described. FIG. 5A is a schematic diagram of a device structure for an experiment having a quantum dot array and two branch paths. In this example, a device has three ports of a source 501, a right drain 502, and a left drain 503, and extracts one electron by using a single-electron pump (single-electron manufacturing unit) formed by three gate electrodes (SG1, FG1, and SG2) from a number of electrons in the source 501. In FIG. 5A, A-A′ indicates one direction of an electron transport path having a two-dimensional lattice shape and B-B′ indicates the other direction.

After that, it is demonstrated that selection of a path of the single electron to the right drain 502 or the left drain 503 can be controlled. FIG. 5B is a schematic diagram of waveforms of potential and input voltage. The path selection is realized by applying an alternating-current (AC) voltage of the same frequency and whose phase is controllable to each of the gate electrode FG1 in the single-electron pump, a gate electrode FG3 (assist gate) before a branch path, and gate electrodes TG1 and TG2 for path selection, and controlling the phase relations of them.

FIG. 5C illustrates an experiment result of the single-electron pump which operates under a 4K (kelvin) environment used to prepare a single electron. The horizontal axis indicates DC voltage of FG2, and the vertical axis indicates I_{D}/(ef). Ip denotes drain current by an electron transported by the single-electron pump, “e” denotes elementary charge, “f” indicates drive frequency of the single-electron pump, and f=100 MHz (consequently, I_{D}=16 pA). From the experiment result, it is confirmed that the single-electron pump operates normally since a plateau is obtained at I_{D}/(ef)=1. The fitting line indicates a result of fitting by a theoretical curve (decay-cascade model) of the single-electron pump operation.

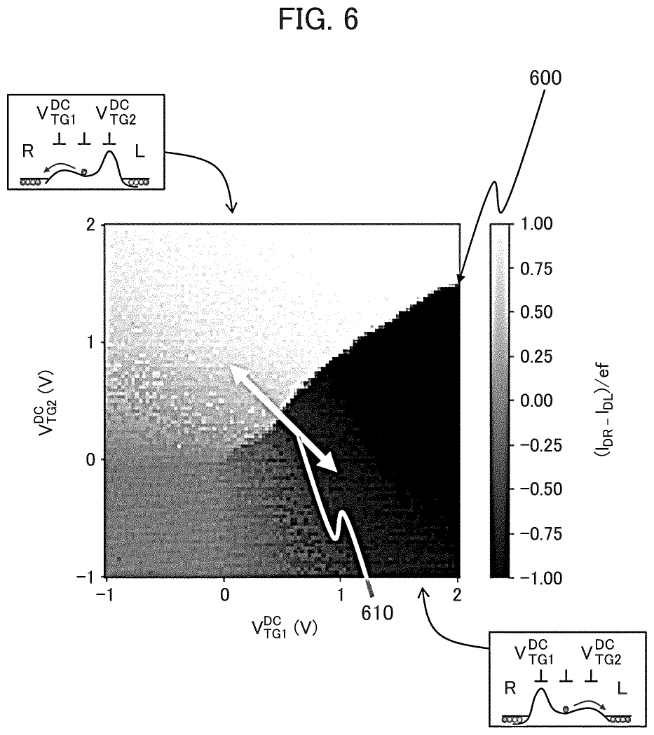

FIG. 6 indicates a result of measurement of the DC characteristic of gate electrodes (TG1 and TG2) for path selection in two branch paths. Current values (I_{DR} and I_{DL}) flowing in the right drain and the left drain, respectively, are changed to the application voltages of TG1 and TG2 which are mapped. The horizontal axis indicates the DC voltage of TG1 and the vertical axis indicates the DC voltage of TG2.

A switching line 600 is a boundary line of I_{DR}−I_{DL}=0. That is, the switching line 600 expresses the voltage condition of TG1 and TG2 at the boundary line for an electron to travel to either the right drain or the left drain. By setting a voltage condition based on the line, the transport path of an electron can be switched. In the experiment, the AC voltage signals whose phases are inverted by 180° were applied to TG1 and TG2 so as to operate on an operating voltage 610.

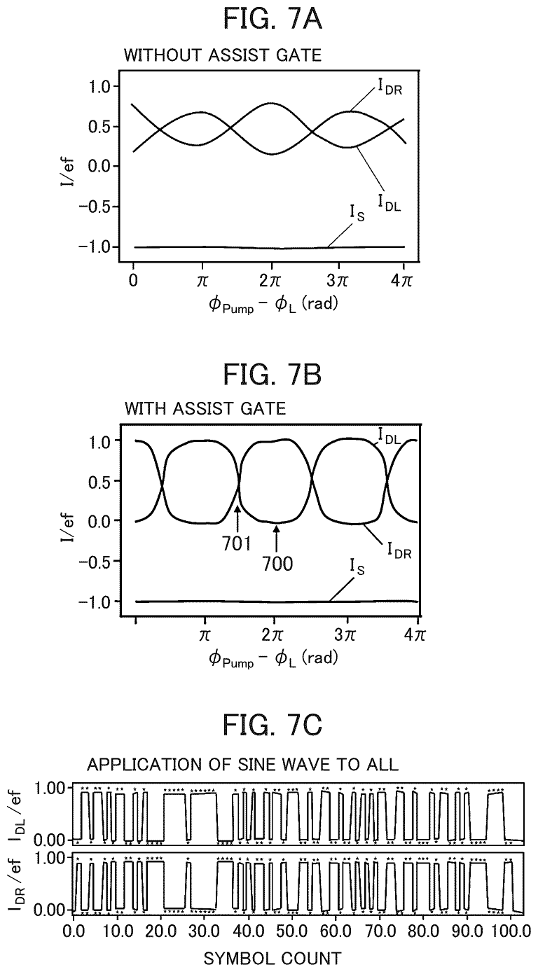

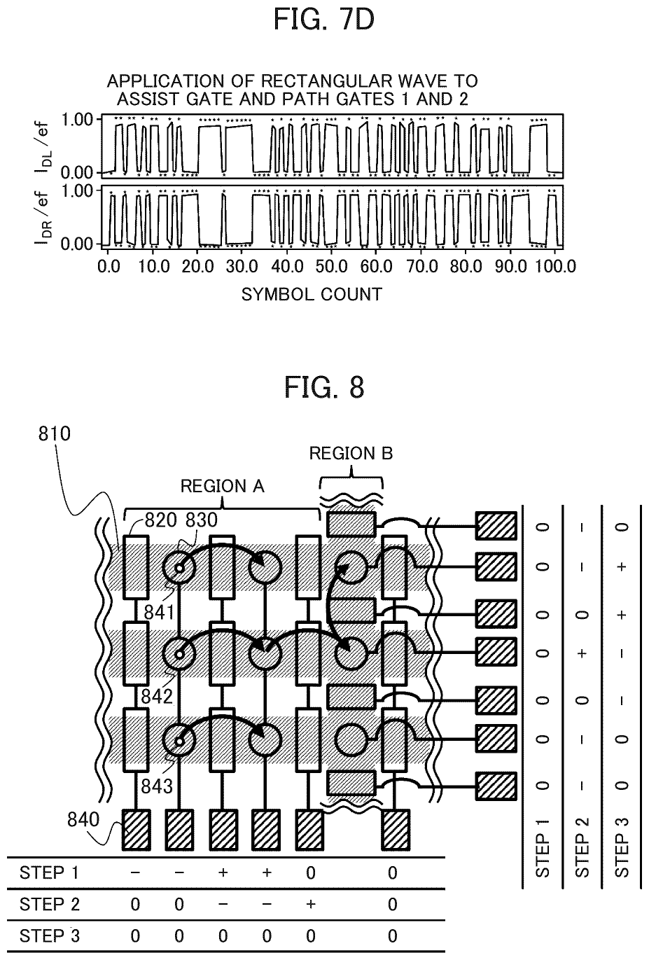

FIG. 7A indicates a result of measurement of currents in the right drain and the left drain in the case of cyclically transporting a single electron by a 100 MHz single-electron pump, operating the gate electrodes (TG1 and TG2) for path selection while inverting the phase, and applying no AC voltage to the assist gate electrode FG3. The horizontal axis indicates a phase difference between AC voltages applied to FG1 and TG1, and the vertical axis indicates a current value measured. Since I_{S}+I_{DR}+I_{DL}=0, it is understood that an electron is properly pumped without back flow. Further, Is denotes a current value of current which is input to a branch. In the case where there is no assist gate operation, it is considered that an electron remains (stagnates) before a branch path until the following electron comes, and it is not easy to perform correct path selection.

On the other hand, in the case where there is an assist gate operation illustrated in FIG. 7B, it is understood that, since an electron which remains before the branch path pushes an electron synchronously with the gate electrodes (TG1 and TG2) for path selection, correct path selection can be easily performed. The phase of the AC voltage applied to the assist gate electrode FG3 is made coincided with the phase of the single-electron pump (FG1). Consequently, the horizontal axis denotes the phase of the AC voltage applied to the assist gate electrode FG3 and the gate electrode TG1 for path selection. It is understood that the path selection is correctly performed at an integral multiple of 180° (n radian) (for example, reference numeral 700 in the diagram). When this phase condition is not satisfied (for example, reference numeral 701 in the diagram), the path selection cannot be performed correctly. From the above, when there is the assist gate driving and the phase relation between the assist gate electrode FG3 and the gate electrodes (TG1, TG2) for path selection is an integral multiple of 180° (n radian), the correct path selection can be easily performed.

FIG. 7C illustrates a result of demonstration of a programmable router operation (path selecting operation). Voltage waveforms having a sine waveform shape are applied to FG1, FG3, TG1, and TG2. FIG. 7D illustrates a result of applying the voltage waveform having a rectangular waveform to FG3, TG1, and TG2. The horizontal axis indicates time series. The vertical axis indicates the left drain current I_{DL} (upper stage) and the right drain current I_{DR} (lower stage). Star marks express correct solutions programmed by using pseudorandom numbers. It is understood that correct path selection can be made in all of 100 symbols. Since a result which is reasonable as a rectangular wave is obtained, it is understood that the assist gate electrode and the gate electrode for path selection can be also controlled by a digital signal.

### Applications

Application examples other than the quantum computer of the above single-electron router will be described. A first application is a single-electron beam splitter. Since a single-electron router can split a single electron at a desired ratio, it can be used as a basic charge control element. For example, it can be used as a divider capable of varying a branching ratio in a circuit system using a stable constant current source employing a single-electrode pump. While a light beam splitter creates a superposition state of photons, a single-electron router splits an electron as particles.

A second application is a single-electron pump error monitor. At the time of using a single-electron pump as a current standard, to monitor whether current is generated at desired precision or not, a controllable electron branch path is useful. Therefore, by performing a current value extraction test at a certain rate and monitoring the current value by using a single-electron router, the stability as a current standard can be maintained.

### Two-Dimensional Continuous Gate Structure

FIG. 8 illustrates an example of electron transport and a path selecting method in the case where gate electrodes in the vertical direction are continuous in a two-dimensional qubit array. As illustrated in the diagram, the structure of a channel 810 (electron transport path), a potential barrier 820, and a quantum dot 830 in a region A and that in a region B are different. In the structure, the regions A and B as basic blocks are repeated. In the region A, gate electrodes above the potential barrier 820 and the quantum dot 830 are continuous in the vertical direction, and almost the same voltage is applied to all of connected gate electrodes by a voltage control unit 840. On the other hand, the region B has a structure in which the channels 810 are connected in the vertical direction, and the gate electrodes immediately above the potential barrier 820 and the quantum dot 830 are separated, so that the voltage can be applied separately.

It is now assumed that electrons (841, 842, and 843) exist in positions as illustrated in the diagram. At this time, in each of the voltage control units 840, a setting of application voltages illustrated in step 1 (− indicates application of voltage in the negative direction, + indicates application of voltage in the positive direction, and 0 indicates maintaining of the present voltage) is performed. By the setting, all of the three electrons are transported to the immediate-right quantum dots at the same time. In such a manner, in the region A, electrons can be transported in a parallel manner by the gate electrodes connected in the vertical direction, so that the number of voltage control units can be reduced.

Subsequently, a setting of application voltages illustrated in step 2 is performed. By the setting, only the electron 842 is further moved to the immediate-right quantum dot, and the remaining two electrons 841 and 843 can be retained in the present quantum dots. In such a manner, by using a region in which a gate electrode can be independently controlled like the region B, only a desired electron can be transported.

After that, a setting of application voltages illustrated in step 3 is performed. By the setting, the electron 842 can be transported upward. By performing proper voltage controls according to the structure as described above, an electron can be transported to a desired position. If the electron 841 does not exist, the steps 2 and 3 can be combined as one step.

### System

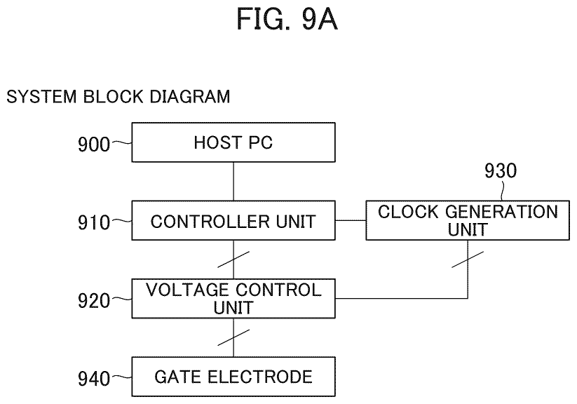

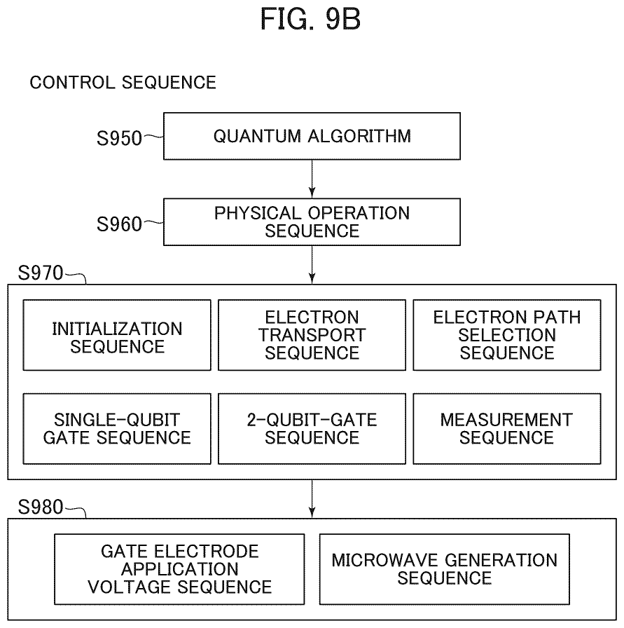

An example of a control system of a quantum computer will now be described. FIG. 9A is a system block diagram of a quantum computer. FIG. 9B illustrates a method of generating a control sequence in a voltage control unit 920 executed mainly in a host PC 900 and a controller unit 910.

The user generates a desired quantum algorithm S950 first. It is expressed by an abstract quantum circuit model or the like. Subsequently, the quantum algorithm S950 is converted to a physical operation sequence S960 which can be implemented in a quantum computer by a program such as a transpiler. Then, a control sequence group S970 of the quantum computer for executing the physical operation sequence is generated. It includes sequences of electron transport and the electron path selection (routing). Subsequently, sequences S980 of the operations of each of the voltage control units and microwave generation operation are generated. The above information is transmitted from the host PC 900 or the controller unit 910 to the voltage control unit 920, a clock generation unit 930 (timing control unit), and other control modules such as a microwave generation unit which are not illustrated in FIG. 9A, and device operation on a gate electrode 940 and the like is performed.

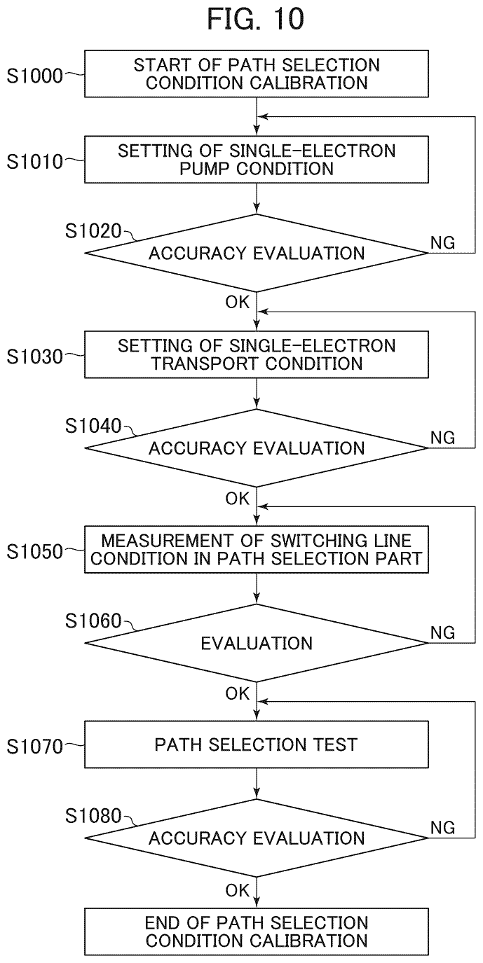

FIG. 10 illustrates a method of calibrating single-electron path selection (single-electron router). The single-electron router calibrating method can be performed by, as an example, the user as a main body. In this case, the user may perform the calibrating method by using a proper device such as a host PC.

In the following, a calibrating method in a part of a path on a quantum dot array will be described. After starting the calibrating method (S1000), first, an operation condition of a single-electron pump for extracting a single electron is set (S1010), and whether the single-electron pump can accurately extract a single electron or not is evaluated (S1020). When it can be checked that the accuracy exceeds preliminarily determined accuracy, an operation condition of single-electron transportation to transport the electron extracted by the single-electron pump is set (S1030), and whether the electron can be accurately transported among quantum dots is evaluated (S1040).

When it can be checked that the accuracy exceeds the preliminarily determined accuracy, for a single-electron router which selects a path for the electron transported by the electron transport, a DC voltage condition of a gate electrode immediately after a path branch part as illustrated in FIG. 6 is set, a switching line condition is measured (S1050), and evaluation is made (S1060).

When it can be checked that the condition is within a preliminarily determined condition range, an operation condition of the single-electron router is set, and whether a path selection can be accurately performed in the path branch part or not is evaluated (S1070). When it can be checked that the accuracy exceeds preliminarily determined accuracy (S1080), the calibration is finished. In the case where the determination in each of the evaluations is negative, resetting of the voltage condition is performed, and re-evaluation is made.

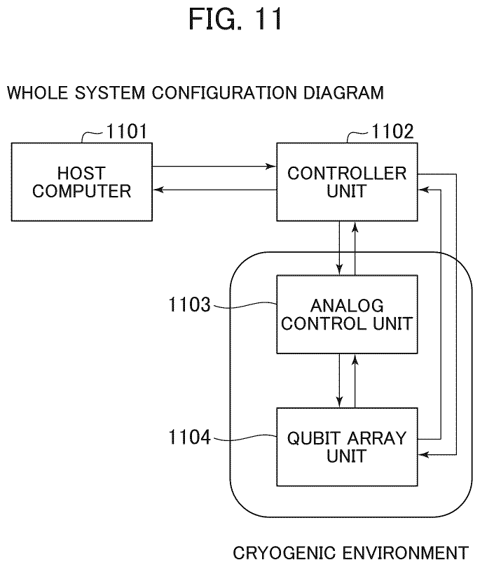

An example of a system configuration of a quantum computer will now be described. FIG. 11 illustrates an outline of a whole configuration diagram of a quantum computer system. A controller unit 1102 which receives a calculation task from a host computer 1101 sends information such as an initialization sequence (refer to S970 in FIG. 9B) to an analog control unit 1103 used for control and a qubit array unit 1104 which are placed in a cryogenic environment. In such a manner, a series of operations of quantum calculation is executed. After that, a qubit state is read, and an obtained read signal (calculation result signal) is transmitted from the qubit array unit 1104 to the controller unit 1102. The read signal is processed by the controller unit 1102 and transmitted to the host computer 1101.

According to the method of the embodiment, for example, in a quantum computer by a large-scale quantum dot array, arrangement of a single electron to a desired position necessary for initialization, computation, and reading of a qubit can be performed.

The embodiment has been described above. However, the present invention is not limited to the foregoing embodiment but includes various modifications and equivalent configurations withing the gist of the scope of claims attached. For example, the foregoing embodiment has been described in detail to facilitate understanding of the present invention. The present invention is not always limited to a device having all of the components described. With respect to a part of the components of the embodiment, addition of another component, elimination, or replacement may be performed.

As described above, a qubit may be a hole in place of an electron. In a manner similar to the case of a single electron, a quantum computer of extracting a single hole by using a gate electrode and selecting a path of the single hole by voltage control may be also provided. Specifically, a quantum computer including a gate electrode array disposed on a semiconductor crystal base, a single-hole manufacturing unit for extracting a single hole, and a hole transport path including a branch and serving as a transport path of the single hole in the semiconductor crystal base, and selecting a path as a branch destination of the single hole by controlling the gate electrode array may be also provided.

In the case of extracting a single hole, a single hole is extracted by a voltage opposite to that in the case of a single electron. In the case of performing single-hole path selection, a path in which application voltage to the gate electrode is increased is not selected, and a path in which application voltage to the gate electrode is decreased is selected. The manner is opposite to that in the case of a single electron.

From the above description, there is provided a single-electron/single-hole transporting method of transporting a single electron or a single hole in a semiconductor crystal base in which a quantum dot array is formed, having: a step of transporting a single electron/single hole along a transport path in a semiconductor crystal base by using the gate electrode array disposed on a transport path in the semiconductor crystal base; and a step of selecting a path as a branch destination of the single electrode/single hole by controlling a voltage of a gate electrode disposed in a position immediately after the branch in the transport path.

Regarding the single-electron/single-hole transporting method, for example, as illustrated in the structure of FIG. 4A, an assist gate electrode (in FIG. 4A, the gate electrode 414) may be further used. That is, in the single-electron/single-hole transporting method, in the step of selecting a path of a single electron/single hole, by further controlling the voltage of a gate electrode disposed in a position immediately before the branch, a path of the single electrode/single hole may be selected.

On the other hand, for example, as illustrated in the structure of FIG. 4B, a structure using a gate electrode immediately after a branch and a gate electrode in the position of the branch may be also employed. That is, in the single-electron/single-hole transporting method, in the step of selecting a path of a single electron/single hole, by further controlling the voltage of a gate electrode disposed in the position of the branch in a transport path, a path of the single electron/single hole may be selected.

The single-electron/single-hole transporting method can be used for an application explained in the above of, for example, a quantum computer or the like as a single-electron router or a single-hole router.

The structure using a semiconductor crystal substrate as an example of the semiconductor crystal base has been described. However, it is sufficient that the semiconductor crystal base has a configuration in which a qubit array is formed and which realizes the transporting method described in the above. The semiconductor crystal base may be, for example, a structure using a bent plate (bent plate of semiconductor crystal) on which a qubit array is formed. The semiconductor crystal base may have a structure in which an oxide film is formed or a structure in which an oxide film is not formed.

### LIST OF REFERENCE SIGNS

303: channel
401, 4023, 403, 404, 405: voltage control unit
410, 412, 414, 416, 418, 420: potential barrier
411, 413, 415, 417, 419, 421: quantum dot

1. A quantum computer comprising:
a gate electrode array disposed on a semiconductor crystal base;
a single-electron manufacturing unit for extracting a single electron; and
an electron transport path including a branch and serving as a transport path of the single electron in the semiconductor crystal base, wherein
a path as a branch destination of the single electron is selected by controlling the gate electrode array.

2. The quantum computer according to claim 1, wherein
a path as a branch destination of the single electron is selected by synchronously applying at least two kinds of voltages to a gate electrode just before the branch to which the single electron moves and a gate electrode immediately after the branch.

3. The quantum computer according to claim 2, further comprising:
a timing control unit; and
at least two voltage control units controlling application voltage at the time of the selection, wherein
a voltage signal which is output from a first voltage control unit and a voltage signal which is output from a second voltage control unit are output synchronously with a signal generated from the timing control unit.

4. The quantum computer according to claim 3, wherein
a voltage signal which is output from the first voltage control unit and a voltage signal which is output from the second voltage control unit are output synchronously with a cyclic signal from the timing control unit, and
a voltage change timing by the first voltage control unit and a voltage change timing by the second voltage control unit almost coincide with each other.

5. The quantum computer according to claim 1, wherein
a path as a branch destination of the single electron is selected by synchronously applying at least two kinds of voltages to a gate electrode in the position of the branch to which the single electron moves and a gate electrode immediately after the branch.

6. The quantum computer according to claim 5, further comprising:
a timing control unit; and
at least two voltage control units controlling application voltage at the time of the selection, wherein
a voltage signal which is output from a first voltage control unit and a voltage signal which is output from a second voltage control unit are output synchronously with a signal generated from the timing control unit.

7. The quantum computer according to claim 6, wherein
a voltage signal which is output from the first voltage control unit and a voltage signal which is output from the second voltage control unit are output synchronously with a cyclic signal from the timing control unit, and
a voltage change timing by the first voltage control unit and a voltage change timing by the second voltage control unit almost coincide with each other.

8. A quantum computer comprising:
a gate electrode array disposed on a semiconductor crystal base;
a single-hole manufacturing unit for extracting a single hole; and
a hole transport path including a branch and serving as a transport path of the single hole in the semiconductor crystal base, wherein
a path as a branch destination of the single hole is selected by controlling the gate electrode array.

9. The quantum computer according to claim 8, wherein
a path as a branch destination of the single hole is selected by synchronously applying at least two kinds of voltages to a gate electrode just before the branch to which the single hole moves and a gate electrode immediately after the branch.

10. The quantum computer according to claim 9, further comprising:
a timing control unit; and
at least two voltage control units controlling application voltage at the time of the selection, wherein
a voltage signal which is output from a first voltage control unit and a voltage signal which is output from a second voltage control unit are output synchronously with a signal generated from the timing control unit.

11. The quantum computer according to claim 10, wherein
a voltage signal which is output from the first voltage control unit and a voltage signal which is output from the second voltage control unit are output synchronously with a cyclic signal from the timing control unit, and
a voltage change timing by the first voltage control unit and a voltage change timing by the second voltage control unit almost coincide with each other.

12. The quantum computer according to claim 8, wherein
a path as a branch destination of the single hole is selected by synchronously applying at least two kinds of voltages to a gate electrode in the position of the branch to which the single hole moves and a gate electrode immediately after the branch.

13. The quantum computer according to claim 12, further comprising:
a timing control unit; and
at least two voltage control units controlling application voltage at the time of the selection, wherein
a voltage signal which is output from a first voltage control unit and a voltage signal which is output from a second voltage control unit are output synchronously with a signal generated from the timing control unit.

14. The quantum computer according to claim 13, wherein
a voltage signal which is output from the first voltage control unit and a voltage signal which is output from the second voltage control unit are output synchronously with a cyclic signal from the timing control unit, and
a voltage change timing by the first voltage control unit and a voltage change timing by the second voltage control unit almost coincide with each other.

15. A single-electron/single-hole transporting method of transporting a single electron or a single hole, comprising:
a step of transporting a single electron/single hole along a transport path in a semiconductor crystal base by using a gate electrode array; and
a step of selecting a path as a branch destination of the single electrode/single hole by controlling a voltage of a gate electrode disposed in a position immediately after the branch in the transport path.
